(19) United States
(12) Patent Application Publication
(10) Pub. No.: US 2025/0301789 A1
(43) Pub. Date: Sep. 25, 2025

(54) PD-SOI TRANSISTORS WITHOUT KINK EFFECT

(71) Applicant: QUALCOMM Incorporated, San Diego, CA (US)

(72) Inventors: Abhijeet PAUL, San Diego, CA (US); Ravi Pramod Kumar VEDULA, San Diego, CA (US)

(21) Appl. No.: 18/610,085

(22) Filed: Mar. 19, 2024

(51) Int. Cl. H01L 27/12; H01L 27/02; H01L 29/10; H10B 10/00

(52) U.S. Cl. CPC H10D 86/201; H10B 10/12; H10D 62/235; H10D 89/10

(57) ABSTRACT

A partially depleted silicon-on-insulator circuit is provided that includes a first transistor having a well-defined source and drain and a second transistor not having a well-defined source or drain. A doped region forms an ohmic contact to a body of the first transistor and the second transistor. Should the first transistor and the second transistor each comprises an NMOS transistor, a silicide layer couples the doped region to the source contact of the first transistor. Conversely, a silicide layer couples the doped region to a drain contact of the first transistor if the first transistor and the second transistor each comprise a PMOS transistor.

### TECHNICAL FIELD

This application relates to transistors, and more particularly to partially depleted silicon-on-insulator (PD-SOI) transistors without kink effect.

### BACKGROUND

Silicon-on-insulator (SOI) transistors have low leakage and other advantageous properties as compared to bulk complementary-metal-oxide semiconductor (CMOS) transistors. As compared to fully depleted silicon-on-insulator (FD-SOI), PD-SOI is markedly less expensive but the partial depletion of the active layer (denoted as the body in SOI technology) results in holes accumulating in the channel near the buried oxide layer. As the holes accumulate, the threshold voltage of a PD-SOI transistor decreases, which results in an increase in drain current denoted as a kink effect.

### SUMMARY

In accordance with an aspect of the disclosure, a partially depleted silicon-on-insulator circuit is provided that includes: a first contact; a first transistor having a source and a first body doped with a first dopant type; a first doped region doped with the first dopant type, wherein the first doped region is doped more heavily than the first body and has a first ohmic contact to the first body; a first silicide layer coupled between the first doped region and the first contact; and a second transistor having a second body doped with the first dopant type, wherein the second body has a second ohmic contact to the first doped region.

In accordance with another aspect of the disclosure, a method of operation for a partially depleted silicon-on-insulator circuit is provided that includes: switching on a first transistor of the partially depleted silicon-on-insulator circuit; conducting holes from a channel of the first transistor through an ohmic contact to a first doped region while the first transistor is switched on; and conducting the holes from the first doped region to a source terminal of a second transistor of the partially depleted silicon-on-insulator circuit.

Finally, in accordance with yet another aspect of the disclosure, a partially depleted silicon-on-insulator circuit is provided that includes: a first NMOS transistor having a first body; a second NMOS transistor having a second body; and a p-doped region having a first ohmic contact to the first body and having a second ohmic contact to the second body, wherein the p-doped region is more heavily doped than the first body and the second body.

These and other advantageous features may be better appreciated through the following detailed description.

### BRIEF DESCRIPTION OF THE DRAWINGS

FIG. 1 is a circuit diagram of an SRAM bitcell in accordance with an aspect of the disclosure.

FIG. 2 illustrates a device-layer layout for an enhanced body-to-source (EBTS) pull-down transistor in the SRAM bitcell of FIG. 1 in accordance with an aspect of the disclosure.

FIG. 3 is a cross-sectional view of the EBTS pull-down transistor of FIG. 2.

FIG. 4 is device-layer layout for a half of the SRAM bitcell of FIG. 1 in accordance with an aspect of the disclosure.

FIG. 5 is a cross-sectional view along line A-A′ of FIG. 4.

FIG. 6 is a cross-sectional view along line B-B′ of FIG. 4.

FIG. 7 illustrates the silicide layers for the half of the SRAM bitcell of FIG. 4 in accordance with an aspect of the disclosure.

FIG. 8 a flowchart of a method of operation for a partially depleted silicon-on-insulator circuit in accordance with an aspect of the disclosure.

FIG. 9 illustrates some example electronic systems including an SRAM bitcell in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

Silicon-on-insulator (SOI) transistors can be classified into two forms: fully depleted SOI (FD-SOI) metal-oxide semiconductor (MOS) and partially depleted SOI (PD-SOI) MOS. In both types of SOI, the active region for the SOI transistors occupies a relatively thin silicon layer that is separated from a bulk silicon substrate by a buried oxide layer. As implied by the name, the channel in FD-SOI MOS devices is fully depleted whereas it is only partially depleted in PD-SOI MOS devices. However, FD-SOI devices are not widely used due to their markedly higher manufacturing costs. Given the partial depletion, the body region of PD-SOI MOS devices is subjected to a floating body effect. For example, in an n-type MOS channel (NMOS) of a PD-SOI transistor, electron-hole pairs result from the channel conduction. The resulting holes collect in the body and reduce the threshold voltage. The reduction in the threshold voltage leads to what is denoted as a kink effect. Should a static random-access memory (SRAM) be formed using PD-SOI transistors, the kink effect leads to various undesirable properties such as a reduced static noise margin (SNM), an increase in variability and defects, and SRAM yield problems for larger-size memories.

To substantially eliminate the kink effect so that circuits such as SRAMs may be formed using PD-SOI transistors, body contact (BC) PD-SOI transistors have been developed. As implied by the designation of “body contact,” BC PD-SOI transistors have a body contact terminal in addition to drain, source, and gate terminals. A body contact device is thus a four-terminal device. Depending upon the polarity (p-type or n-type) of the channel body, the body contact terminal is either tied to a power supply terminal (for p-type transistors) or tied to ground (for n-type transistors) so that the carriers that would otherwise cause the kink effect can be conducted out of the channel to the body contact terminal. Although body contact devices thus address the kink effect, the use of four terminals causes an increase in the semiconductor die area needed to implement each device and also results in routing complexity to the four terminals. The additional body contact terminal is thus an impediment to achieving high-density SRAM bitcells that occupy a reduced semiconductor die space in the IC (integrated circuit).

To address the die space demands and routing complexity of a body contact approach, a PD-SOI transistor body-to-source (BTS) architecture has been developed that uses a doped region having an ohmic contact to the body and also couples though a silicide layer to source contact. The doped region is doped more heavily but of the same polarity (n-type or p-type) as the channel and thus forms the ohmic contact to the body. The silicide layer covers both the doped region and the source so that the carriers that would otherwise cause the kink effect may conduct from the channel through the doped region and the silicide layer to a source contact. As compared to the body contact approach, a BTS transistor is more compact and does not need a body terminal. But BTS transistors require well-defined source and drain terminals. Transistors that do not have well-defined source and drain terminals such as the access transistors in an SRAM bitcell are not amenable to being formed as BTS transistors.

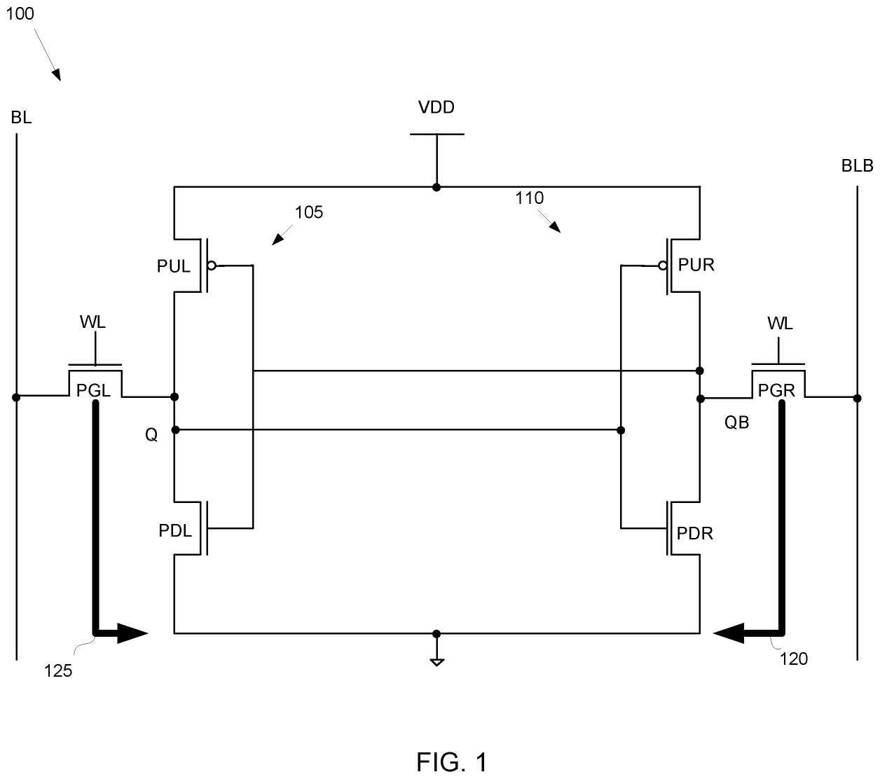

To provide a better appreciation of why SRAM bitcell access transistors cannot be implemented as BTS transistors, an example SRAM bitcell 100 is shown in FIG. 1. The SRAM bitcell 100 stores a bit through the action of a pair of cross-coupled inverters 105 and 110. Each inverter is formed by a serial stack of a p-type metal-oxide semiconductor (PMOS) transistor and an n-type metal-oxide semiconductor (NMOS) transistor. The PMOS transistor functions as a pull-up transistor whereas the NMOS transistor functions as a pull-down transistor with respect to an output node of the inverter. In the first inverter 105, a pull-up transistor is denoted as a pull-up left (PUL) transistor since the first inverter 105 is on the left-side of the bitcell 100. Similarly, a pull-down transistor in the first inverter 105 is denoted as a pull-down left (PDL) transistor. A source of the PUL transistor couples to a power supply node for a memory power supply voltage VDD whereas a drain of the PUL transistor couples to a drain of the PDL transistor. A source of the PDL transistor couples to ground.

The drain of each of the PUL and PDL transistors forms an output node Q for the bitcell 100 that couples through an NMOS access transistor to a bit line (BL). The NMOS access transistor may also be denoted as a pass-gate left (PGL) transistor. A word line (WL) couples to a gate of the PGL transistor such that when a voltage of the word line is asserted to the memory power supply voltage to switch on the PGL transistor, the Q output node from the bitcell 100 is coupled to the bit line.

The second inverter 110 is formed analogously as discussed for the first inverter 105 and thus includes a pull-up right transistor (PUR) and a pull-down right (PDR). The drain of each of the PUR and PDR transistors forms a complement output node QB for the inverter 110 that couples through a pass-gate right (PGR) NMOS access transistor to a complement bit line (BLB) when the word line voltage is asserted. Should the bitcell 100 be storing a binary one bit, the Q output node is charged to the memory power supply voltage VDD whereas the QB output node is grounded. Conversely, the Q output node is grounded and the QB output node charged to the memory power supply voltage VDD should the bitcell 100 be storing a binary zero bit.

The variable charging or grounding of the Q and QB output nodes raises the following issue. Note that each pull-up and pull-down transistor in each of the inverters 105 and 110 has a well-defined source such that the inverters 105 and 110 may be implemented as BTS PD-SOI transistors. But what is a source or drain for the PGL and PGR access transistors is not well defined because the Q and QB output nodes may either be charged to the memory power supply voltage VDD or grounded depending upon the binary content of the bitcell 100. The PGL and PGR access transistors thus cannot be implemented as BTS PD-SOI transistors. The resulting kink effect in the access transistors is quite undesirable.

To advantageously address the kink effect so that the bitcell 100 may be implemented using PD-SOI technology, the pull-down transistors PDL and PDR may each be implemented as what is denoted herein as an enhanced BTS transistor. In an enhanced BTS (EBTS) transistor, a doped region not only forms the BTS coupling in the EBTS transistor but also functions as the body contact to a transistor not having a well-defined source or drain. Holes that would otherwise accumulate in the channel of the transistor not having a well-defined source or drain are thus conducted through an ohmic contact to the doped region and from the doped region to a silicide layer on the doped region and from the silicide layer to the source contact of the EBTS transistor. Referring again to the bitcell 100, the resulting coupling of the holes from the body of the PGR access transistor to the PDR transistor source contact is represented by arrow 120. Similarly, the coupling of the holes from the body of the PGL access transistor to the PDL transistor source contact is represented by arrow 125. The following discussion will focus on an SRAM bitcell implementation in which the EBTS transistor is a pull-down transistor and in which the body contact transistor is a corresponding PG access transistor. But it will be appreciated that the EBTS transistor may be implemented in any partially depleted silicon-on-insulator circuit in which a PD-SOI transistor having a well-defined source and drain has either a drain or source coupled to a drain/source terminal of another PD-SOI transistor not having a well-defined source and drain.

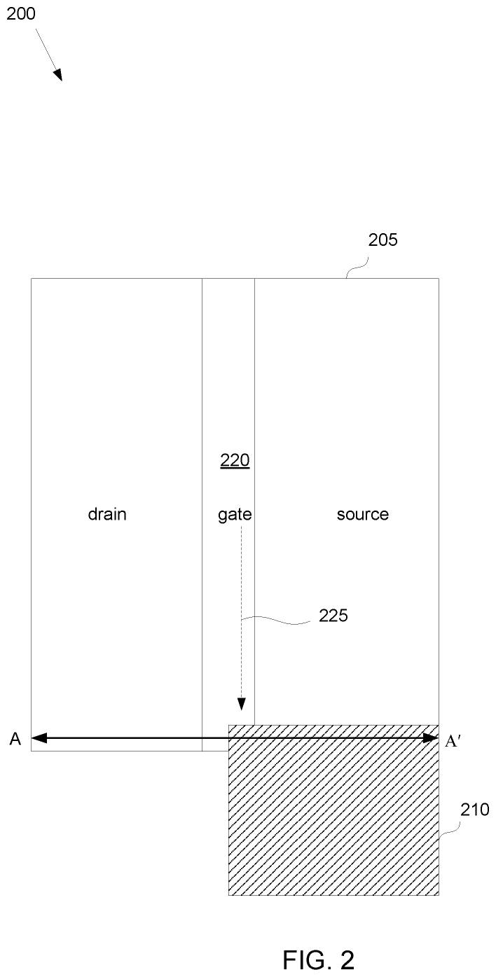

A layout for an example EBTS pull-down transistor 200 is shown in FIG. 2. A diffusion region 205 is doped n-type and divided into a source and a drain region by a gate 220 (e.g., a polysilicon gate). A length of the gate 220 defines a length of the channel for the transistor 200 whereas a width of the gate 220 defines a width of the channel. With respect to the channel length, the gate may be deemed to extend from one end of the channel length to another end of the channel length. A p+ doped region 210 is formed at one of the ends of the channel length (the base of the gate 220). A width of the doped region 210 extends from approximately a center of the gate 220 across a width of the source. Since the body (the channel beneath the gate 220) is doped p-type and the doped region 210 is doped p+, the doped region 210 forms an ohmic contact to the body.

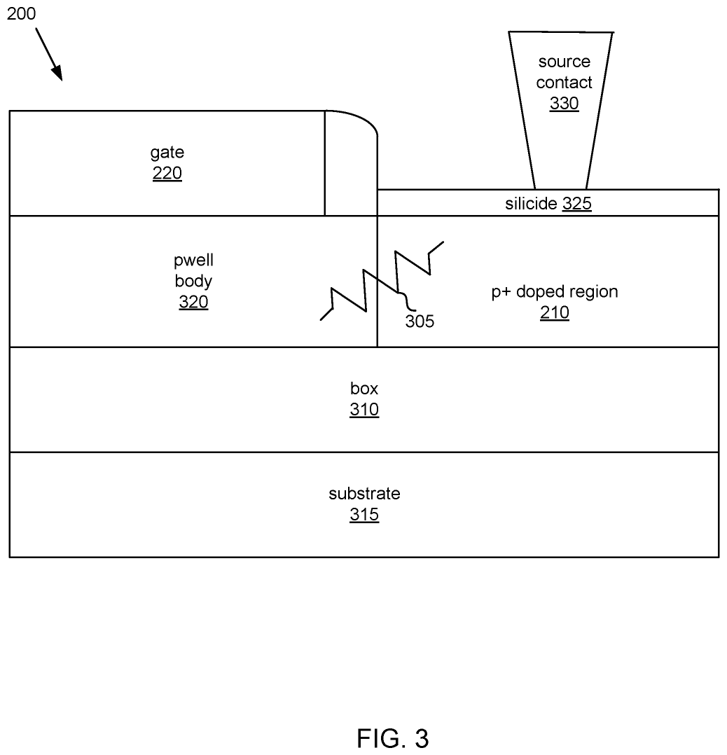

This ohmic contact is also shown in the cross-sectional view of the EBTS transistor 200 in FIG. 3 taken along line A-A′ of FIG. 2. A buried oxide region (box) 310 separates a p-well (pwell) body 320 from a substrate 315. The gate 220 is insulated from the pwell body 320 by a silicon dioxide layer (not illustrated). A silicide layer 325 couples the p+ doped region 210 to a source contact 330 such as a via that couples to the source (FIG. 2). Referring again to FIG. 2, the holes 225 in the channel of the EBTS transistor 220 conduct as shown by the arrow for the holes 225 from the channel to the doped region 210. As shown in FIG. 3, the holes may then conduct through the ohmic contact 305 between the body 320 and the doped region 210 and from the doped region 210 through the silicide layer 325 to the source contact 330.

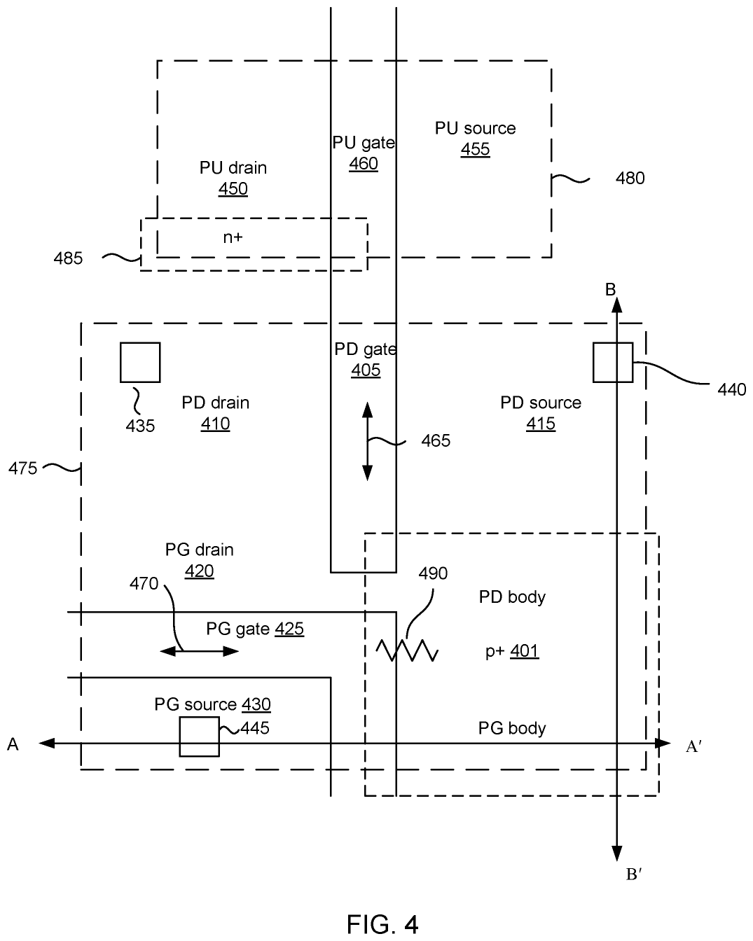

Referring again to the SRAM bitcell 100, note that each inverter and corresponding access transistor may be deemed to form a half of the bitcell 100. In each bitcell half, the pull-down transistor may have a p+ implant that not only couples between the pull-down transistor's body and source but also couples to the body of the corresponding access transistor. An example half of a bitcell 400 is shown in FIG. 4 that includes a pull-down (PD) transistor, a pull-up (PU) transistor, and a corresponding pass-gate (PG) access transistor. A gate 405 for the pull-down transistor extends to also form a gate 460 for the PU transistor. A longitudinal axis 465 of the PD gate 405 is orthogonal to a longitudinal axis 470 of a gate 425 for the PG transistor. The PG transistor is thus rotated by 90 degrees with respect to PD and PU transistors as defined by their gates' longitudinal axes. The PG gate 425 is L-shaped such that it has a 90-degree turn from its longitudinal axis 470 that is parallel with the PD gate 405.

Since the PD and PG transistors are n-type transistors, the PD and PG transistors are formed in a n-type diffusion region 475 implanted in a p-type silicon-on-insulator (SOI) layer. The PD gate 405 divides the diffusion region 475 into a drain 410 and a source 415 for the PD transistor. The PD gate 405 shields the underlying channel from the n-type implantation forming diffusion region 475 so that the channel remains p-type. Similarly, the PG gate 425 divides the diffusion region 475 into a drain 420 and a source 430 of the PG transistor. It will be appreciated that the drain 420 and source 430 of the PG transistor are more properly denoted as drain/source terminals since a source is not well defined for the PG transistor as discussed earlier. Thus, the following discussion will refer to the drain 420 and source 430 of the PG transistor merely for convenience since there is no well-defined source for the PG transistor. The PG gate 425 also shields the underlying channel from the n-type implantation forming the diffusion region 475 so that the channel of the PG transistor remains p-type. As will be explained further, a silicide layer (not shown in FIG. 4) shorts together the drains 410 and 420 of the PD and PG transistors so that may be coupled to a common drain contact 435. A source contact (which may also be denoted as a via) 440 couples to the source 415 of the PD transistor. The source contact 440 is an example of a first contact as defined herein. Similarly as discussed for the source contact 440, a source contact 445 couples to the source 430 of the PG transistor. A p+ doped region 401 has an ohmic contact to the PD body and the PG body. For example, the body of the PG transistor couples through an ohmic contact 490 to the p+ doped region 401. Note how the orthogonal orientation of the PD and PG transistors allows the doped region 401 to extend along a base of each of the PD gate 405 and the PG gate 425 so that holes from the corresponding channels may ohmically couple to the doped region 401 yet the resulting die space required for the SRAM bitcell 400 is advantageously compact.

Since the PU transistor is a p-type transistor, its drain 450 and source 455 are formed in a p-type diffusion region 480 implanted in an n-type SOI layer. The gate 460 shields the underlying channel from the implantation forming diffusion region 480 so that the channel of the PU transistor remains n-type. An n+ doped region 485 forms a body-to-drain (BTD) coupling between the drain 450 and the body of the PU transistor. The doped region 485 extends approximately across half the width of the channel of the PU transistor at one end of the length of the channel. Electrons that would otherwise accumulate in the channel of the PU device are thus conducted to the drain 450 through the doped region 485.

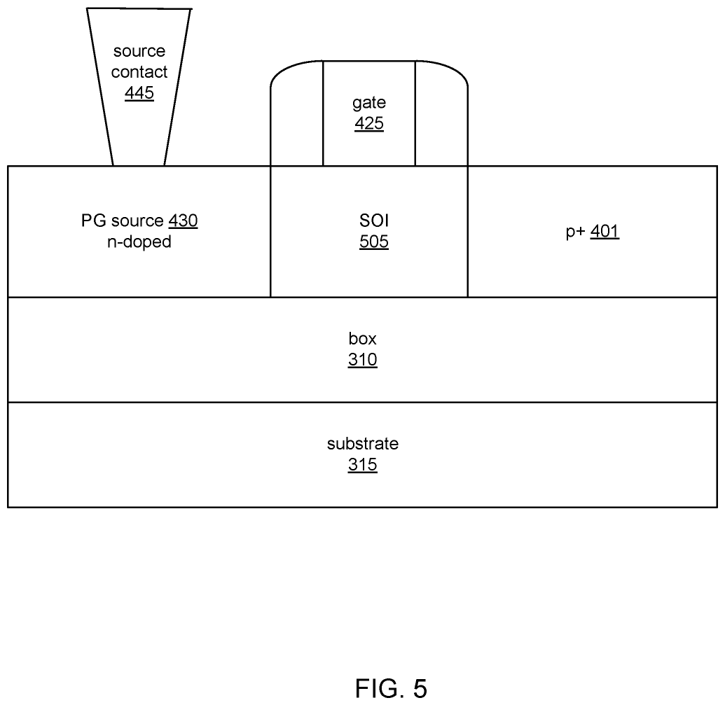

A cross-sectional view of the SRAM bitcell 400 along the line A-A′ of FIG. 4 is shown in FIG. 5. A silicon dioxide insulating layer (not illustrated) insulates the PG gate 425 from a p-type SOI body 505. The p+ doped region 401 has an ohmic coupling to the SOI body 505. The n-type source 430 of the PG transistor couples to the source contact or via 445 through a corresponding silicide layer (not illustrated). The buried oxide layer (box) 310 and substrate 315 are arranged as discussed for the EBTS transistor 200 of FIG. 3.

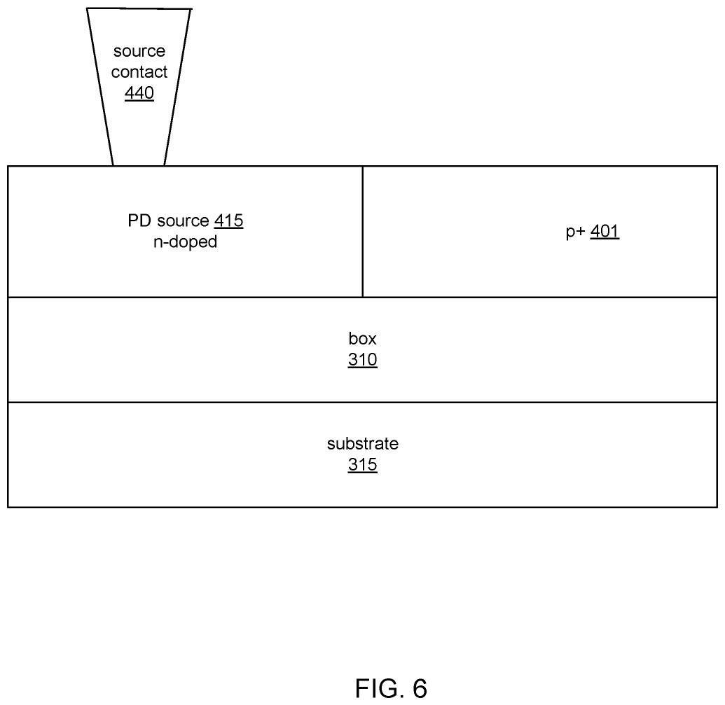

A cross-sectional view of the SRAM bitcell 400 along the line B-B′ of FIG. 4 is shown in FIG. 6. The n-doped PD source 415 couples to the source contact or via 440. Both the PD source 415 and the p+ doped region 401 are separated from the substrate 315 by the buried oxide layer (box) 310.

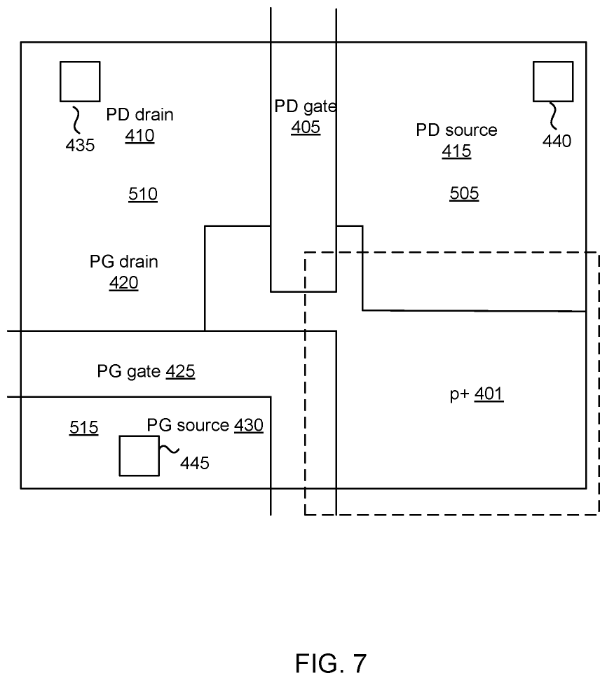

The silicide layers for the half SRAM bitcell 400 are shown in FIG. 7. A silicide layer 505 lies above a portion of the p+ doped region 401 and the PD source 415 to electrically short or couple them together. Similarly, a silicide layer 510 is deposited over the PD drain 410 and the PG drain 420 to couple these drains to the drain contact 435. Finally, a silicide layer 515 deposited over the PG source 430 couples the PG source 430 to the source contact 445.

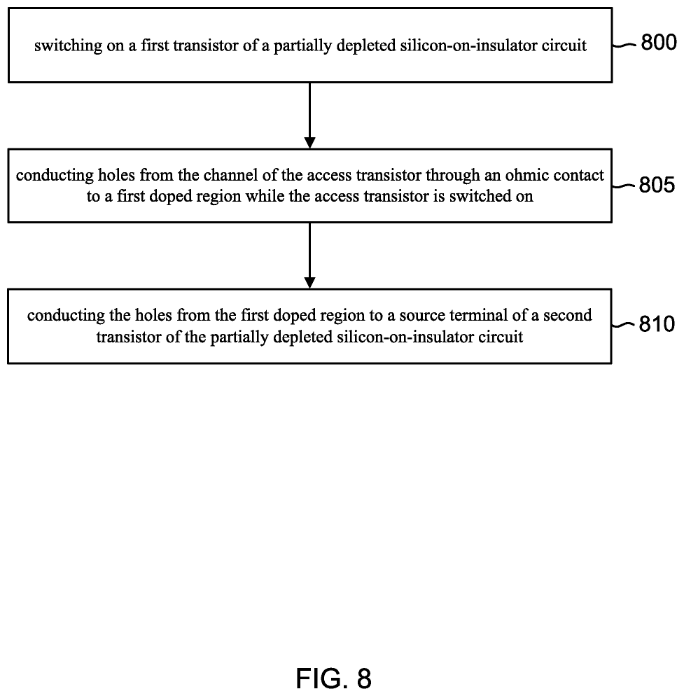

A flowchart for a method of operating an EBTS transistor and a corresponding transistor not having a well-defined source is shown in FIG. 8. The method includes an act 800 of switching on a first transistor of a partially depleted silicon-on-insulator circuit. The switching on of either the PGR or the PGL access transistors in the SRAM bitcell 100 is an example of act 800. The method also includes an act 805 of conducting holes from the channel of the first transistor through an ohmic contact to a first doped region while the first transistor is switched on. The conducting of holes from the channel underneath the PG gate 425 through the ohmic contact 490 of FIG. 4 to the p+ doped region 401 is an example of act 805. Finally, the method includes an act 810 of conducting the holes from the first doped region to a source terminal of a second transistor of the partially depleted silicon-on-insulator circuit. The conducting of the holes from the p+ doped region 401 through the silicide layer 505 of FIG. 7 to the source contact 440 is an example of act 810.

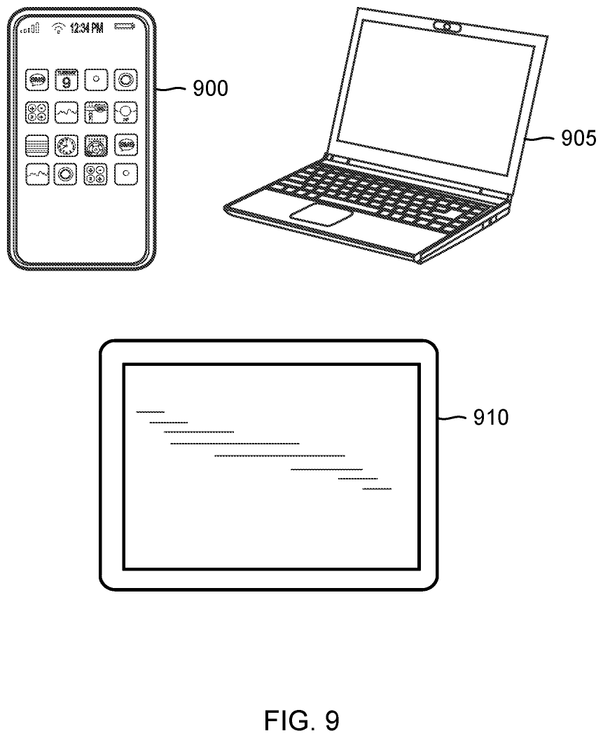

An SRAM including a plurality of the SRAM bitcells 100 as disclosed herein may be incorporated in a wide variety of electronic systems. For example, as shown in FIG. 9, a cellular telephone 900, a laptop computer 905, and a tablet PC 910 may all include an SRAM with SRAM bitcells implemented in accordance with the disclosure. Other exemplary electronic systems such as an earbud, a music player, a video player, a communication device, and a personal computer may also be configured with an SRAM constructed in accordance with the disclosure.

The disclosure will now be summarized in the following series of example clauses:

Clause 1. A partially depleted silicon-on-insulator circuit, comprising:
a first contact;
a first transistor having a source and a first body doped with a first dopant type;
a first doped region doped with the first dopant type, wherein the first doped region is doped more heavily than the first body and has a first ohmic contact to the first body;
a first silicide layer coupled between the first doped region and the first contact; and
a second transistor having a second body doped with the first dopant type, wherein the second body has a second ohmic contact to the first doped region.

Clause 2. The partially depleted silicon-on-insulator circuit of clause 1, wherein the first transistor further includes a first gate having a first longitudinal axis and the second transistor further includes a second gate having a second longitudinal axis that is perpendicular to the first longitudinal axis.

Clause 3. The partially depleted silicon-on-insulator circuit of clause 2, wherein the first dopant type is an n-type dopant, and wherein the first contact is a first source contact and the second gate is L-shaped.

Clause 4. The partially depleted silicon-on-insulator circuit of clause 3, wherein the partially depleted silicon-on-insulator circuit comprises a static random-access memory (SRAM) bitcell.

Clause 5. The partially depleted silicon-on-insulator circuit of clause 4, wherein the first transistor is a n-type metal-oxide semiconductor (NMOS) pull-down transistor in a first inverter of the SRAM bitcell, and wherein the second transistor is an NMOS access transistor of the SRAM bitcell.

Clause 6. The partially depleted silicon-on-insulator circuit of any of clauses 3-5, wherein the first doped region extends from a base of the first gate to a base of the second gate.

Clause 7. The partially depleted silicon-on-insulator circuit of any of clauses 5-6, wherein the first inverter further includes a p-type metal-oxide semiconductor (PMOS) pull-up transistor, and wherein the first gate extends along its first longitudinal axis to also form a gate of the PMOS pull-up transistor.

Clause 8. The partially depleted silicon-on-insulator circuit of any of clauses 5-7, further comprising:
a drain contact coupled to a drain of the NMOS pull-down transistor through a second silicide layer.

Clause 9. The partially depleted silicon-on-insulator circuit of any of clauses 7-8, further comprising:
a p-type doped region having a second ohmic contact to a body of the PMOS pull-up transistor, wherein the p-type doped region is more heavily doped than the body of the PMOS pull-up transistor.

Clause 10. The partially depleted silicon-on-insulator circuit of any of clauses 5-9, wherein the SRAM bitcell is included within a cellular telephone.

Clause 11. A method of operation for a partially depleted silicon-on-insulator circuit, comprising:
switching on a first transistor of the partially depleted silicon-on-insulator circuit;
conducting holes from a channel of the first transistor through an ohmic contact to a first doped region while the first transistor is switched on; and
conducting the holes from the first doped region to a source terminal of a second transistor of the partially depleted silicon-on-insulator circuit.

Clause 12. The method of clause 11, wherein switching on the first transistor comprises switching on an access transistor of an SRAM bitcell, and wherein conducting the holes from the first doped region to the source terminal of the second transistor comprises conducting the holes from the first doped region to a source terminal of a pull-down transistor of the SRAM bitcell.

Clause 13. The method of clause 12, further comprising:
conducting electrons from a channel of a pull-up transistor of the SRAM bitcell through a second doped region to a drain terminal of the pull-up transistor.

Clause 14. The method of any of clauses 12-13, further comprising:
conducting the holes from the source terminal of the pull-down transistor to ground.

Clause 15. A partially depleted silicon-on-insulator circuit, comprising:
a first NMOS transistor having a first body;
a second NMOS transistor having a second body; and
a p-doped region having a first ohmic contact to the first body and having a second ohmic contact to the second body, wherein the p-doped region is more heavily doped than the first body and the second body.

Clause 16. The partially depleted silicon-on-insulator circuit of clause 15, wherein the partially depleted silicon-on-insulator circuit comprises an SRAM bitcell having a first inverter that is cross-coupled to a second inverter, and wherein the first NMOS transistor comprises a pull-down transistor of the first inverter.

Clause 17. The partially depleted silicon-on-insulator circuit of clause 16, further comprises:
a first silicide layer configured to couple the p-doped region to a source of the pull-down transistor.

Clause 18. The partially depleted silicon-on-insulator circuit of any of clauses 16-17, wherein the second NMOS transistor comprises an access transistor of the SRAM bitcell, and wherein a longitudinal axis of a gate of the pull-down transistor is orthogonal to a longitudinal axis of a gate of the access transistor.

Clause 19. The partially depleted silicon-on-insulator circuit of clause 18, wherein the first inverter further includes a PMOS pull-up transistor, wherein the gate of the pull-down transistor is extended along its longitudinal axis to also form a gate of the PMOS pull-up transistor.

Clause 20. The partially depleted silicon-on-insulator circuit of clause 19, further comprising an n-doped region coupled between a body of the PMOS pull-up transistor and a drain contact of the PMOS pull-up transistor.

It will be appreciated that many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. A partially depleted silicon-on-insulator circuit, comprising:
a first contact;
a first transistor having a source and a first body doped with a first dopant type;
a first doped region doped with the first dopant type, wherein the first doped region has a first ohmic contact to the first body;
a first silicide layer coupled between the first doped region and the first contact; and
a second transistor having a second body doped with the first dopant type, wherein the second body has a second ohmic contact to the first doped region, wherein the first doped region is doped more heavily than the first body and the second body.

2. The partially depleted silicon-on-insulator circuit of claim 1, wherein the first transistor further includes a first gate having a first longitudinal axis and the second transistor further includes a second gate having a second longitudinal axis that is perpendicular to the first longitudinal axis.

3. The partially depleted silicon-on-insulator circuit of claim 2, wherein the first dopant type is an n-type dopant, and wherein the first contact is a first source contact and the second gate is L-shaped.

4. The partially depleted silicon-on-insulator circuit of claim 3, wherein the partially depleted silicon-on-insulator circuit comprises a static random-access memory (SRAM) bitcell.

5. The partially depleted silicon-on-insulator circuit of claim 4, wherein the first transistor is a n-type metal-oxide semiconductor (NMOS) pull-down transistor in a first inverter of the SRAM bitcell, and wherein the second transistor is an NMOS access transistor of the SRAM bitcell.

6. The partially depleted silicon-on-insulator circuit of claim 5, wherein the first doped region extends from a base of the first gate to a base of the second gate.

7. The partially depleted silicon-on-insulator circuit of claim 5, wherein the first inverter further includes a p-type metal-oxide semiconductor (PMOS) pull-up transistor, and wherein the first gate extends along its first longitudinal axis to also form a gate of the PMOS pull-up transistor.

8. The partially depleted silicon-on-insulator circuit of claim 5, further comprising:
a drain contact coupled to a drain of the NMOS pull-down transistor through a second silicide layer.

9. The partially depleted silicon-on-insulator circuit of claim 7, further comprising:
a p-type doped region having a third ohmic contact to a body of the PMOS pull-up transistor, wherein the p-type doped region is more heavily doped than the body of the PMOS pull-up transistor.

10. The partially depleted silicon-on-insulator circuit of claim 5, wherein the SRAM bitcell is included within a cellular telephone.

11. A method of operation for a partially depleted silicon-on-insulator circuit, comprising:
switching on a first transistor of the partially depleted silicon-on-insulator circuit;
conducting holes from a channel of the first transistor through an ohmic contact to a first doped region while the first transistor is switched on; and
conducting the holes from the first doped region to a source terminal of a second transistor of the partially depleted silicon-on-insulator circuit.

12. The method of claim 11, wherein switching on the first transistor comprises switching on an access transistor of an SRAM bitcell, and wherein conducting the holes from the first doped region to the source terminal of the second transistor comprises conducting the holes from the first doped region to a source terminal of a pull-down transistor of the SRAM bitcell.

13. The method of claim 12, further comprising:
conducting electrons from a channel of a pull-up transistor of the SRAM bitcell through a second doped region to a drain terminal of the pull-up transistor.

14. The method of claim 12, further comprising:
conducting the holes from the source terminal of the pull-down transistor to ground.

15. A partially depleted silicon-on-insulator circuit, comprising:
a first NMOS transistor having a first body;
a second NMOS transistor having a second body; and
a p-doped region having a first ohmic contact to the first body and having a second ohmic contact to the second body, wherein the p-doped region is more heavily doped than the first body and the second body.

16. The partially depleted silicon-on-insulator circuit of claim 15, wherein the partially depleted silicon-on-insulator circuit comprises an SRAM bitcell having a first inverter that is cross-coupled to a second inverter, and wherein the first NMOS transistor comprises a pull-down transistor of the first inverter.

17. The partially depleted silicon-on-insulator circuit of claim 16, further comprises:
a first silicide layer configured to couple the p-doped region to a source contact of the pull-down transistor.

18. The partially depleted silicon-on-insulator circuit of claim 16, wherein the second NMOS transistor comprises an access transistor of the SRAM bitcell, and wherein a longitudinal axis of a gate of the pull-down transistor is orthogonal to a longitudinal axis of a gate of the access transistor.

19. The partially depleted silicon-on-insulator circuit of claim 18, wherein the first inverter further includes a PMOS pull-up transistor, wherein the gate of the pull-down transistor is extended along its longitudinal axis to also form a gate of the PMOS pull-up transistor.

20. The partially depleted silicon-on-insulator circuit of claim 19, further comprising an n-doped region coupled between a body of the PMOS pull-up transistor and a drain contact of the PMOS pull-up transistor.
